(19) United States
(12) Patent Application Publication
(10) Pub. No.: US 2001/0035348 A1
(43) Pub. Date: Nov. 1, 2001

(54) Target array for an arc vapor deposition chamber including arc vapor deposition source and target plates thereof

(76) Inventor: Hans Braendle, Sargans (DE)

Correspondence Address: CROWELL & MORING LLP, Intellectual Property Group, P. O. Box 14300, Washington, DC, 20044-4300, US

(21) Appl. No.: 09/805,459

(22) Filed: Mar. 14, 2001

Related U.S. Application Data
(63) Continuation of application No. PCT/CH98/00394, filed on Sep. 14, 1998.

(51) Int. Cl. C23C 14/32

(52) U.S. Cl. 204/298.41; 204/192.38

(57) ABSTRACT

An arc vapor deposition source has a target plate to be vaporized. A central surface area of the plate, on a vaporization-surface-side thereof, consists of a material which, in comparison to a remaining portion material of the target plate, has a low secondary electron emission rate and a low surface energy. The central surface area is formed by a detachable cover. The target plate has a continuous recess in a central area thereof and an insert therein forms the surface area. The material of the central surface area consists of at least one of boron nitride, hexagonal boron nitride and/or TiN. The target plate is surrounded by a frame having a surface that consists of a material which compared to the material of the target plate, has a lower secondary electron emission rate and a low surface energy. The material of the frame being the same as that of the surface area and/or the frame surface consisting of at least one of boron nitride, hexagonal boron nitride and TiN.

### CROSS-REFERENCE TO RELATED APPLICATIONS

This application is a Continuation of PCT Application No. PCT/CH98/00394 filed on Sep. 14, 1998.

### BACKGROUND OF THE INVENTION

The present invention relates to an arc vapor deposition source as well as to target plates therefor.

One of the known PVD (Physical Vapor Deposition) processes consists of generating a plasma in the form of a maximum-current low-voltage arc discharge on a material source, the target. In this process, the material to be evaporated is placed as a cathode (target) on the negative pole of a voltage source. The arc is ignited by an ignition device, such as an ignition finger. The arc melts the cathode at one or several cathode spots in which the current conduction is concentrated, the arc moving more or less stochastically on the cathode surface, unless additional measures are taken to guide this movement. An extremely rapid heating-up of small target surface areas takes place, whereby material is evaporated locally and macroscopic spatters of the molten mass are ejected and deposit as undesirable layer defects as “droplets” on the surfaces to be coated. The movement of the arcs and thus of the cathode spots, as it occurs particularly in the so-called “random arc” process, depends particularly on the target material and on the pressure. It can—in the case of the so-called “steered arc” process—be influenced and controlled, among other things, by magnetic fields in order to, for example, guide the arc on a defined path on the target surface.

Because of the high current densities (10⁶ to 10⁸ A/cm²) in the area of the cathode spot, the above-mentioned spatter formation of droplets will occur. These are the larger, the more slowly the arc moves over the surface and the larger the considered cathode spot develops.

The measures known so far for avoiding droplets have various disadvantages:

A guiding of the arc on the target surface, as provided in the case of the “steered-arc” process, is described, for example, in the essays by Engin Ertürk, et al. with the titles “Protection against Wear by TiN Coating according to the ION BOND Process” (VDI-Z, Vol. 129, 1987, No. 1) , and “Protection against Wear for Tools” (Industrieanzeiger 21, 1989) and in the International Patent Application WO 89/01699. Although, with these known processes, the occurrence of droplets is reduced, high technical expenditures are required for this purpose for a magnetic system necessary for controlling the arc.

U.S. Pat. No. 4,929,321, the formation of droplets is largely avoided in that the substrate to be coated is arranged outside the visual contact with the targets. However, in this known arrangement, the coating rate is unfavorably low.

In addition, according to U.S. Pat. No. 4,919,968, for reducing the formation of droplets, an array with several targets is suggested which permit a mutual vapor deposition. This known array uses a double source and thus requires additional higher investments.

For reasons of completeness, reference is finally made to other teachings for avoiding droplets. These known teachings are described in the essays by Vasin et al. with the title “Vacuum Arc with a Distributed Discharge on an Expendable Cathode” (Sov. Techn. Phys. Lett. 5, 1979, No. 12, Page 634 to 636) and by Aksenov et al. with the title “Transport of Plasma Streams in a Curvilinear Plasma-Optics System” (Sov. J. Plasma Phys. 4, 1978, No. 4, Pages 425 to 428) and are characterized particularly in that they require extremely high technical expenditures.

### SUMMARY OF THE INVENTION

It is therefore an object of the present invention to provide an arc vapor deposition source in the case of which the formation of droplets is eliminated or at least considerably reduced. This object has been achieved by providing an arc vapor deposition source comprising a target plate to be vaporized, where a central surface area of the plate, on a vaporization-surface-side thereof, consists of a material which, in comparison to a remaining portion material of the target plate, has a low secondary electron emission rate and a low surface energy.

The invention has the following advantages: In that a central area of the surface of the target plate consists of a material which, in comparison to the material to be vaporized, has a lower secondary electron emission rate (SEER) and a lower surface energy, it is surprisingly possible to achieve at least a significant reduction or a complete elimination of the formation of droplets. This is particularly surprising since it contradicts the opinion of previous teachings. It had been assumed that an avoidance of droplets could be achieved the more easily, the more the substrates to be coated are arranged over the central area of the target surface. Thus, Engin Ertürk teaches in “Protection against Wear by TiN Coating according to the ION BOND Process” (VDI-Z, Vol. 129, 1987, No. 1) that droplets occur mainly at an angle of between 20° and 30° with respect to the surface of the target surface to be vaporized.

### BRIEF DESCRIPTION OF THE DRAWINGS

Other objects, advantages and novel features of the present invention will become apparent from the following detailed description of the invention when considered in conjunction with the accompanying drawings.

FIG. 1 is a schematic side view of a source according to the invention with a target plate according to the invention;

FIG. 2 is a view of the vapor deposition profile on the target plate of a conventional arc vapor deposition source; and

FIG. 3 is a view of a vapor deposition profile on the target plate according to the invention of a source according to the invention;

### DETAILED DESCRIPTION OF THE DRAWINGS

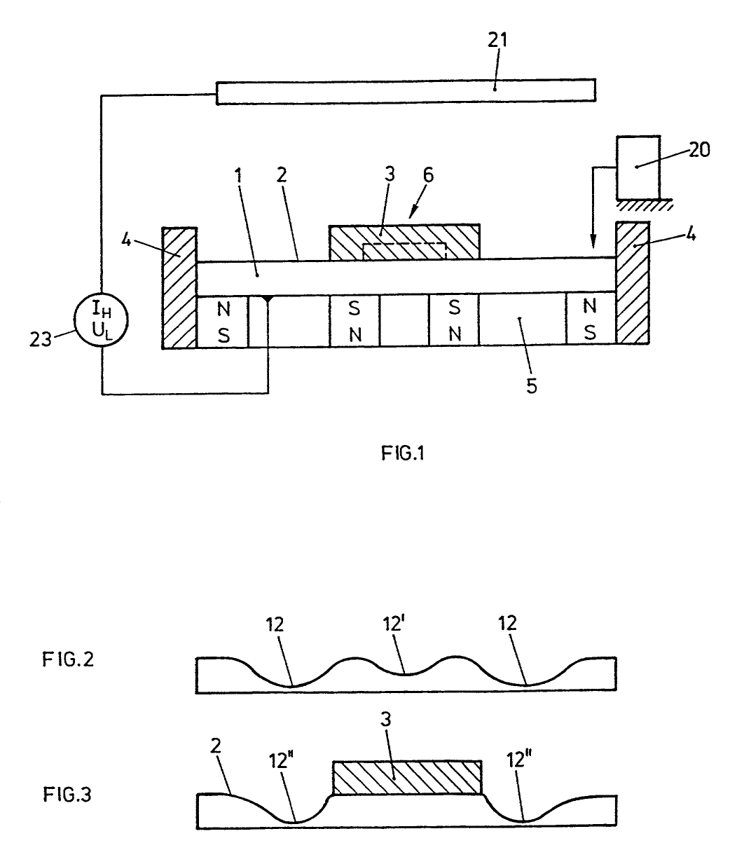

FIG. 1 illustrates an arc vapor deposition source according to the invention, as used in an arc vapor deposition chamber for the coating of substrates. It normally comprises an ignition device 20—as illustrated purely schematically—for igniting the arc. Furthermore, again illustrated purely schematically, an electric high-current—I_{H}—, low-voltage—U_{L}—DC source 23 is connected between the target plate 1 and an anode 21. The source comprises the target plate 1 with the surface 2 to be vaporized, optionally a frame 4 and a cover 3 which, according to the invention, is arranged in a central area 6 and consists of a material which, in comparison to the target plate 1, has a lower secondary electron emission rate and a lower surface energy.

The frame 4 encloses the target plate 1 and preferably consists of a material which—corresponding to the material of the cover 3—in comparison to the material of the target plate 1, has a low secondary electron emission rate and a low surface energy. If the frame 4 surrounds the target plate 1 in a form-locking manner, a spark-over of the arc from the material plate 1 to other parts of the chamber can be prevented. Preferred materials for the frame 4 and for the cover are, for example, boron nitride and/or hexagonal boron nitride and/or titanium nitride.

In order to further reduce or completely eliminate the formation of droplets, it is provided in a preferred embodiment of the invention to arrange a magnet system 5 below the target plate 1, in which case, the individual magnets, whether they are solenoids with an adjustable magnetic field or permanent magnets, can be at least partially displaceable. The target array according to the invention is therefore used in combination with an above-mentioned “steered-arc” process, whereby an even better droplet protection for the substrate surfaces to be coated is achieved.

The target plate 1 preferably has a circular construction, as well as preferably the cover 3. However, the target plate 1 and/or the cover 3 may also have an elliptic, polygonal, for example, hexagonal, rectangular or square shape. The central area of the target plate is essentially its centroidal area.

In another embodiment of the source according to the invention, the target plate 1 has, instead of a cover 3, a central, continuous or not continuous recess at the site of the cover of FIG. 1. An insert of a material or at least with a surface is embedded into this recess, which material or surface is that of or is made of the material specified for the cover 3. As a result, the target plate 1, as illustrated in FIG. 1, can be constructed as a plate in a continuously flat manner and, for forming the central surface according to the invention, has the cover 3. In another embodiment, the surface of the target plate 1 has a forming-in in the mentioned central area, in which the insert is placed, like a pill, which forms the above-mentioned surface. In still another embodiment, the plate 2 has a continuous central opening, and the above-mentioned surface area is formed by an insert in this opening, whether it is constructed, for example, in the shape of a mushroom or as a pin. In any case, in the insert of the source, the above-mentioned surface area of the target plate is made of the above-mentioned material.

FIG. 2 illustrates an arc vapor deposition removal profile on the target plate of a known arc vapor deposition source. Three vapor deposition removal maxima are clearly visible at 12 and 12′, in the area of the removal maximum 12′, despite the low removal of the target plate, significantly more droplets are emitted than, for example, in the area of the removal maximum 12.

FIG. 3 shows an arc vapor deposition removal profile on a source or target plate according to the invention. As a result of the cover or the insert 3 in the area of the removal maximum 12′ illustrated in FIG. 2, an increased vapor deposition removal takes place in the area of the removal maxima 12″, while undesirable droplets are simultaneously reduced or completely eliminated.

The foregoing disclosure has been set forth merely to illustrate the invention and is not intended to be limiting. Since modifications of the disclosed embodiments incorporating the spirit and substance of the invention may occur to persons skilled in the art, the invention should be construed to include everything within the scope of the appended claims and equivalents thereof.

What is claimed is:

1. Arc vapor deposition source comprising a target plate to be vaporized, where a central surface area of the plate, on a vaporization-surface-side thereof, consists of a material which, in comparison to a remaining portion material of the target plate, has a low secondary electron emission rate and a low surface energy.

2. Source according to claim 1, wherein the central surface area is formed by a detachable cover.

3. Source according to claim 1, wherein the target plate has a continuous recess in a central area thereof and an insert therein forms the surface area.

4. Source according to claim 3, wherein the central surface area is formed by a detachable cover.

5. Source according to claim 1, wherein the material of the central surface area consists of at least one of boron nitride, hexagonal boron nitride and TiN.

6. Source according to claim 5, wherein the central surface area is formed by a detachable cover.

7. Source according to claim 6, wherein that the target plate has a continuous recess in a central area thereof and an insert therein forms the surface area.

8. Source according to claim 1, wherein that the central surface area has a circular disk-shaped.

9. Source according to claim 1, wherein a magnet system is provided below the target plate.

10. Source according to claim 1, wherein the target plate is surrounded by a frame having a surface that consists of a material which compared to the material of the target plate, has a lower secondary electron emission rate and a low surface energy and at least one of the material of the frame being the same as that of the surface area and the frame surface consisting of at least one of boron nitride, hexagonal boron nitride and TiN.

11. Source according to claim 1, wherein an ignition device is provided for igniting an arc.

12. Source according to claim 11, wherein the target plate is circular-disk-shaped.

13. Target plate for a source according to claim 1, wherein a vaporization-surface-side of the central surface area of the plate consists of a material which, compared to remaining material of the target plate, has a low secondary electron emission rate and a low surface energy.

14. Target plate part for a source according to claim 1, wherein the central forming-in on a vaporization surface thereof is one of continuous and non-continuous.
